(19) United States
(12) Patent Application Publication
(10) Pub. No.: US 2009/0125255 A1
(43) Pub. Date: May 14, 2009

(54) METHODS AND APPARATUS FOR MEASURING VOLTAGE AND VOLTAGE PHASE ANGLE ON BPL LINE

(76) Inventor: Michael Keselman, San Ramon, CA (US)

Correspondence Address: DICKSTEIN SHAPIRO LLP, 1825 EYE STREET NW, Washington, DC, 20006-5403, US

(21) Appl. No.: 12/268,214

(22) Filed: Nov. 10, 2008

Related U.S. Application Data
(60) Provisional application No. 60/996,270, filed on Nov. 8, 2007.
(60) Provisional application No. 60/996,271, filed on Nov. 8, 2007.

(51) Int. Cl. G01R 23/12; G01R 19/00; G01R 21/00

(52) U.S. Cl. 702/60; 324/76.52; 702/64

(57) ABSTRACT

An apparatus for measuring voltage in a broadband over power line system including a first load having a first predetermined impedance, and a second load having a second predetermined impedance. Wherein the apparatus is contained within a capacitor-based BPL coupler. Also a method of measuring a voltage and a phase angle in a broadband over power line system comprising attaching a voltage divider to a medium voltage power line, measuring a voltage and a phase angle at said voltage divider and calculating said voltage and the phase angle based on the measured voltage and the measured phase angle. Wherein the voltage divider may be placed within a coupler along the broadband over power line system.

### CROSS-REFERENCE TO RELATED APPLICATIONS

This application claims the benefit of U.S. Provisional Appl. No. 60/996,270 filed Nov. 8, 2007, and U.S. Provisional Appl. No. 60/996,271 filed Nov. 8, 2007, the entire disclosures of which are incorporated herein by reference.

### FIELD OF THE INVENTION

The invention is directed toward measuring the voltage and voltage phase angle on a power line in a broadband over power line (BPL) system.

### BACKGROUND OF THE INVENTION

Broadband communications services can be provided using one or more high-voltage cables of a power distribution network, while the power distribution network supplies electrical power. A radio-frequency signal at a first location (or node) is modulated with a data signal and coupled to a high-voltage cable serving as a transmission channel. At a second node the radio-frequency signal is coupled from the high-voltage cable to a demodulator for converting the modulated signal back to a data signal. Data is sent from the second node to the first node in a similar manner typically using a different band of frequencies. This full-duplex broadband service between the locations may simultaneously supply a variety of communication needs, such as telephone service, video service, Internet service, and other services requiring high-speed data transfers. Part of the BPL system is a coupler which connects the BPL equipment to a power line. The coupler provides physical connectivity to the line to transfer the BPL signal, but it can be used for other purposes too.

Since data can be sent over the power line, various “smart grid” systems have been used. Such systems may read a customer's electric power meter remotely or even remotely manipulate devices at the customer site. Another use of such systems is to read various characteristics of the power line itself. Conventional methods of reading power line characteristics require specialized equipment to read the line and to collect the data. Detecting the presence and/or measuring the value of the voltage on the power line and measuring the voltage phase angle on multi-phase power lines are some of the best indicators of whether a power grid is about to malfunction or fail, causing power outages.

Accordingly, there is a need and desire for reading the value and presence of voltage and voltage phase angles on power lines to identify and locate potential power outages.

### BRIEF SUMMARY OF THE INVENTION

1. An apparatus for measuring voltage in a broadband over power line system including a first load having a first predetermined impedance, and a second load having a second predetermined impedance. Wherein the apparatus is contained within a capacitor-based BPL coupler. Also a method of measuring a voltage and a phase angle in a broadband over power line system comprising attaching a voltage divider to a medium voltage power line. Further comprising, measuring a voltage and a phase angle at the voltage divider and calculating the voltage and the phase angle based on the measured voltage and the measured phase angle. Wherein the voltage divider may be placed within a coupler along the broadband over power line system.

### BRIEF DESCRIPTION OF THE DRAWINGS

FIG. 1 is a schematic diagram of a BPL system constructed in accordance with an embodiment described herein;

FIG. 2 is a block diagram of an apparatus for measuring voltage and voltage phase angle on a power line constructed in accordance with the embodiment described herein;

FIG. 3 is a block diagram of an apparatus for measuring voltage and voltage phase angle on a power line where the measuring is contained in a capacitor-based coupler constructed in accordance with the embodiment described herein; and

FIG. 4 is a schematic diagram of a system for measuring and comparing the voltage phase angles of multiple phases on a multi-phase power line constructed in accordance with an embodiment described herein.

### DETAILED DESCRIPTION OF THE INVENTION

In the following detailed description, reference is made to the accompanying drawings, which form a part hereof and show by way of illustration specific embodiments in which embodiments of the present invention may be practiced. These embodiments are described in sufficient detail to enable those skilled in the art to practice them, and it is to be understood that other embodiments may be utilized, and that structural, logical, processing, and electrical changes may be made. The progression of processing steps described is an example; however, the sequence of steps is not limited to that set forth herein and may be changed as is known in the art, with the exception of steps necessarily occurring in a certain order.

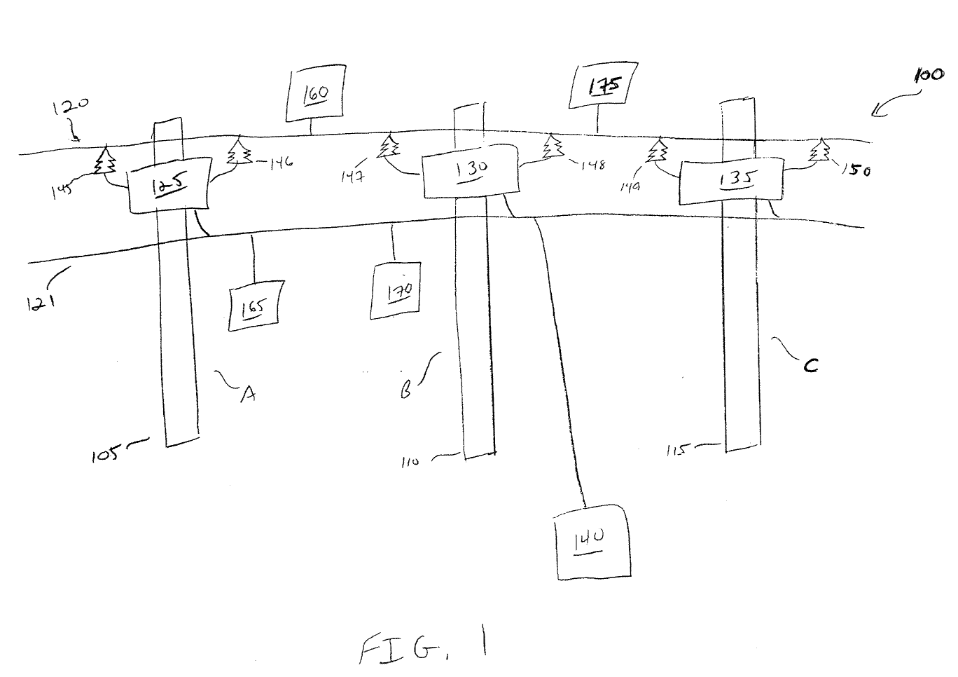

Now referring to the figures, where like numerals designate like elements, FIG. 1 is a schematic diagram of a BPL system 100 constructed in accordance with an embodiment described herein. BPL system 100 includes first, second, and third utility poles 105, 110, 115; a medium-voltage power line 120; a low-voltage power line 121; first, second, and third BPL regenerators 125, 130, 135; and a customer site 140 connected to the low-voltage power line 121 near the second regenerator 130 for receiving the broadband signal. First through sixth BPL couplers 145-150 are connected between the BPL regenerators 125, 130, 135 and the medium-voltage power line 120.

BPL system 100 further includes components 160, 165, 170, 175, which can be any other typical components found in a power grid and connected to any part of the grid, e.g., transformers, arresters, reclosers, and taps. Each utility pole 105, 110, 115 connected to a respective regenerator 125, 130, 135 is a node A, B, C. Each node has two couplers 145-150 connected to it, one for receiving the BPL signal at a first frequency, and the other for transmitting the BPL signal at a second frequency. It should be noted that every utility pole in a power grid may not have a BPL regenerator. The medium-voltage power line 120 may be a single-phase or multi-phase power line, such as a three-phase power line.

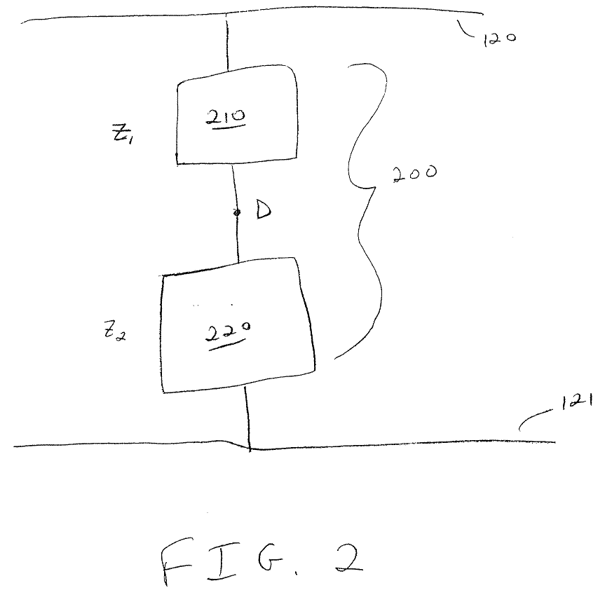

FIG. 2 is a block diagram of an apparatus 200 for measuring voltage or voltage phase angle on a power line constructed in accordance with an embodiment described herein. Apparatus 200 includes a first load 210 having a first predetermined impedance Z₁. Apparatus 200 further includes a second load 220 having a second predetermined impedance Z₂. The first and second loads 210, 220 are connected to each other at node D. The apparatus 200 is connected between the medium-voltage power line 120 and neutral wire 121, and forms a voltage divider at node D. The neutral wire 121 may also be a ground wire. The phase angle can be measured at the node D of the voltage divider. The voltage V_{M} at the medium-voltage power line 120 can be calculated according to:

$${V}_{M} = {V}_{D} * ( \frac{{Z}_{1} + {Z}_{2}}{{Z}_{2}} ) \qquad ( 1 )$$

where V_{M} is the voltage at the medium-voltage power line, V_{D} is the voltage measured across the second load 220 at node D, and Z₁ and Z₂ are the respective impedances of the first and second loads 210, 220.

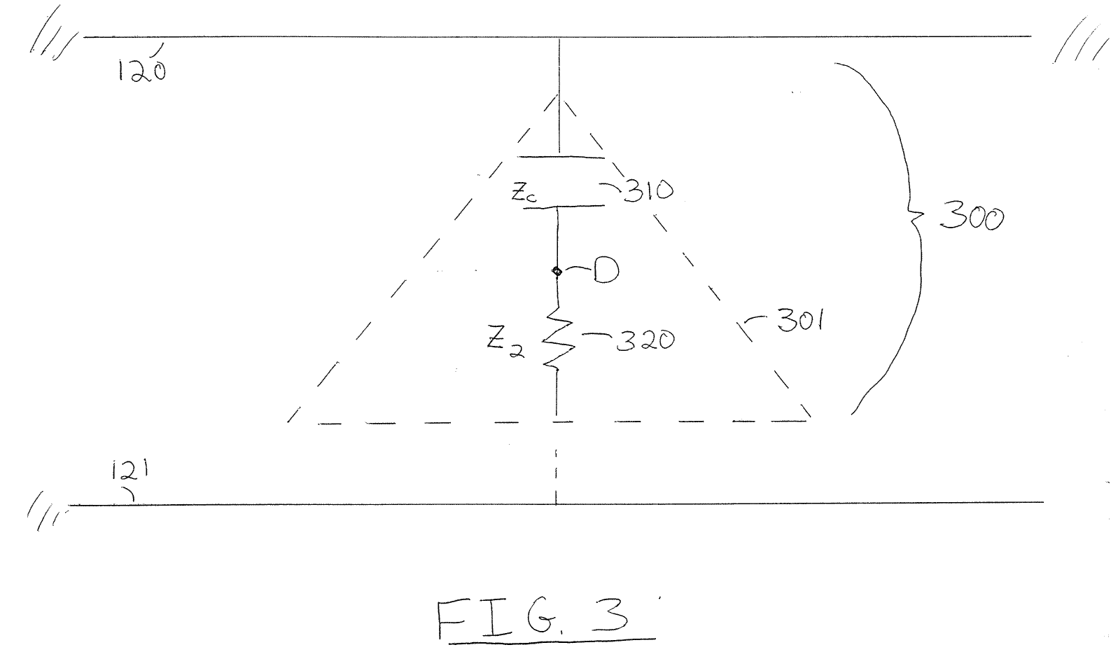

FIG. 3 illustrates a further embodiment of an apparatus 300 for measuring voltage and voltage phase angle on a power line in a BPL system constructed in accordance with an embodiment described herein. The apparatus includes a voltage divider built into one of the BPL couplers 145-150, the coupler being represented in this case by capacitor-based BPL coupler 301. The first load 310 is the predetermined native capacitance of the capacitor-based BPL coupler 301. The second load 320 may be a resistor or other resistive device. The second load 320 is built into the BPL coupler 301. The apparatus 300 forms a voltage divider at node D. The apparatus 300 is connected between the medium-voltage power line 120 and the low-voltage power line 121.

The voltage V_{M} at the medium-voltage power line 120 can be calculated according to:

$${V}_{M} = {V}_{D} * ( \frac{{Z}_{C} + {Z}_{2}}{{Z}_{2}} ) \qquad ( 2 )$$

where V_{M} is the voltage at the medium-voltage power line, V_{D} is the voltage measured across the second load 320 at node D, Z_{C} is the capacitance 310 of the capacitor-based BPL coupler 301, and Z₂ is the impedance of the second load 320.

Another exemplary method of measuring the phase angle of a medium-voltage power line 120 is to isolate a 60 Hz frequency from the RF BPL signal and measure the 60 Hz frequency. Adding a shift capacitor to the sensor shifts the voltage phase angles by 90°, which should be taken into account when comparing phase angles from multiple medium-voltage power lines. A shift resistor may also be used in place of the shift capacitor; however it may increase the capacitance, and this affects the RF BPL signal.

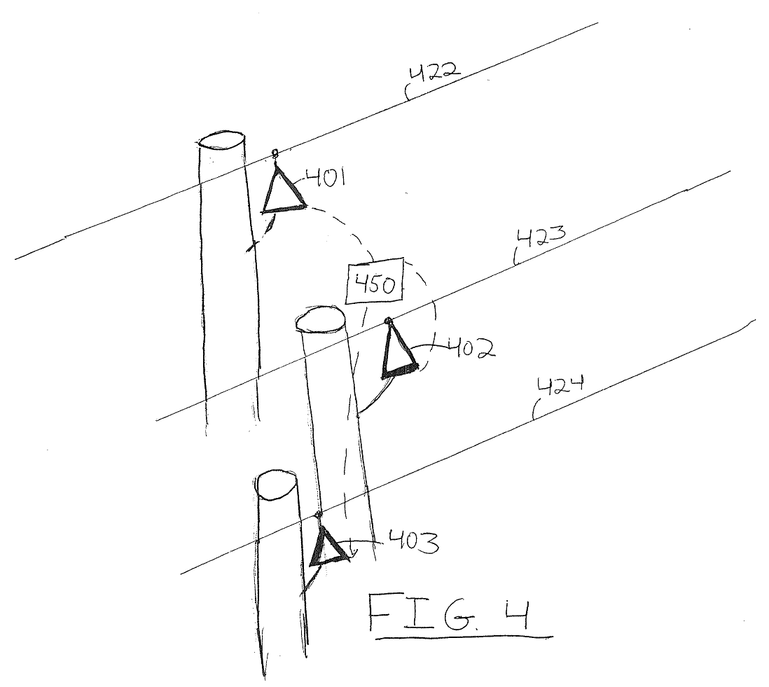

FIG. 4 illustrates a schematic diagram of a system 400 for measuring voltage phase angle on a BPL system on a multi-phase power line. Medium-voltage power lines 422, 423, 424 each have an apparatus 401, 402, 403 for measuring their respective phase angles, consistent with an embodiment of the present invention. Ideally, the phase angles of each phase in the multi-phase power line system are equal. The respective phase angles of the medium-voltage power lines 422, 423, 424 are then communicated to a phase angle comparing device 450. Phase angle comparing device 450 may be a processor configured to receive phase angle measurements, or a circuit configured to receive values (such as voltages) representing the detected phase angles, and output another value (such as another voltage) representing a difference between the detected phase angles. It should be understood that several methods of comparing measured phase angles are known in the art, and the phase angle comparing device 450 is not limited to the above-described embodiments. The respective phase angles are compared to each other, and if they are not equal, or not within a predetermined tolerance, correction may be required. The voltage phase angles and the comparison results may be reported automatically to a remote location (not shown) such as a power station or office, for instance by a data collection device (not shown). The result may be the comparison alone or a warning that correction is needed.

In both FIGS. 2 and 3, the power on the medium-voltage power line 120 can also be calculated according to:

P=V_{M}*I (3)

where P is the power, V_{M} is the voltage at the medium-voltage power line, and I is a current measured at the medium-voltage power line 120.

The determined voltage and voltage phase angle at the medium-voltage power line V_{M} and power P may be reported automatically to a remote location such as a power station or office, for instance by a data collection device.

The processes and devices in the above description and drawings illustrate examples of methods and devices of many that could be used and produced to achieve the objects, features, and advantages of embodiments described herein. For example, embodiments include receiving and transmitting the same signal frequency at each node A-C while still avoiding interference. Thus, the embodiments are not to be seen as limited by the foregoing description of the embodiments, but only limited by the appended claims.

What is claimed as new and desired to be protected by Letters Patent of the United States is:

1. A method of measuring a voltage and a phase angle in a broadband over power line system, said method comprising the steps of:
attaching a voltage divider to a medium voltage power line;
measuring a voltage and a phase angle at said voltage divider; and
calculating said voltage and said phase angle based on said measured voltage and said measured phase angle.

2. The method of claim 1, wherein said placing a voltage divider step comprises placing said voltage divider within a coupler along the broadband over power line system.

3. The method of claim 2, wherein said voltage divider comprises the native impedance of the coupler and the resistance of a resistive element.

4. The method of claim 1, further comprising reporting said measured phase angle and said measured voltage to a remote location.

5. The method of claim 1, further comprising comparing said phase angle of a first power line to a phase angle of a second power line.

6. The method of claim 5, further comprising reporting a result of said comparison to a remote location.

7. An apparatus for measuring a voltage and a voltage phase angle of a power line in a broadband over power line system, said apparatus comprising:
a first load having a first predetermined impedance; and
a second load having a second predetermined impedance coupled to said first load.

8. The apparatus of claim 7, wherein said first load comprises a capacitance.

9. The apparatus of claim 7, wherein said second load comprises a resistance.

10. The apparatus of claim 7, wherein said voltage on said power line is calculated by a processor according to:
$${V}_{M} = {V}_{D} * ( \frac{{Z}_{1} + {Z}_{2}}{{Z}_{2}} ) ,$$
where V_{M} is said calculated voltage at said power line, V_{D} is said voltage measured across said second load at a node between said first and second loads, and Z₁ and Z₂ are said respective impedances of said first and second loads.

11. The apparatus of claim 10, wherein a power level on said power line is calculated according to:
P=V_{M}*I
where P is said calculated power level, V_{M} is said voltage at said power line, and I is a current measured at said power line.

12. The apparatus of claim 7, wherein said voltage phase angle is measured at a node between said first and second loads.

13. The apparatus of claim 7, wherein said apparatus is contained within a capacitor-based BPL coupler.

14. The apparatus of claim 13, wherein:
said first load comprising the native capacitance of the coupler; and
said second load consisting of a resistive load.

15. The apparatus of claim 14, wherein said voltage on said power line is calculated according to:
$${V}_{M} = {V}_{D} * ( \frac{{Z}_{C} + {Z}_{2}}{{Z}_{2}} ) ,$$
where V_{M} is said calculated voltage at said power line, V_{D} is said voltage measured across said second load at a node between said first and second loads, Z_{C} is said capacitance of said coupler, and Z₂ is the impedance of said second load.

16. The apparatus of claim 15, wherein a power level on said power line is calculated according to:
P=V_{M}*I
where P is said calculated power level, V_{M} is said voltage at said power line, and I is a current measured at said power line.

17. A system for monitoring a voltage phase angle on a multi-phase power line, comprising:
multiple apparatuses for measuring the voltage phase angle of a power line, wherein one or more said apparatuses is enclosed within a coupler of a broadband over power line system attached to said power line; and
a voltage phase angle comparing device to compare voltage phase angle measurements of the multiple apparatuses.

18. The system of claim 17, wherein if the result of the comparison of the voltage phase angel comparing device of the voltage phase angel measurements are not within a predetermined tolerance, repair action or notification occurs.
